(19) United States
(12) Patent Application Publication
(10) Pub. No.: US 2026/0066864 A1
(43) Pub. Date: Mar. 5, 2026

(54) RF VARIABLE GAIN AMPLIFIER USING CURRENT STEERING AND CURRENT CANCELLATION TECHNIQUES FOR HIGH RESOLUTION RF PHASE SHIFTERS

(71) Applicant: Samsung Electronics Co., Ltd., Gyeonggi-do (KR)

(72) Inventors: Anirban SARKAR, Castro Valley, CA (US); Siuchuang Ivan LU, San Jose, CA (US)

(21) Appl. No.: 19/320,820

(22) Filed: Sep. 5, 2025

Related U.S. Application Data
(60) Provisional application No. 63/691,105, filed on Sep. 5, 2024.

(51) Int. Cl. H03G 3/30; H03H 11/16

(52) U.S. Cl. CPC H03G 3/3036; H03H 11/16; H03G 2201/103; H03G 2201/307

(57) ABSTRACT

A system and a method are disclosed for RF variable gain amplification using a combination of current steering and current cancellation techniques. An active radio frequency (RF) variable gain amplifier (VGA) architecture is disclosed that combines current steering and current cancelling techniques to achieve fine gain resolution, low phase variation, and improved attenuation for high-resolution RF phase shifters. The disclosed VGA integrates an m-bit current steering portion with an n-bit current cancelling portion, each comprising binary weighted slices with a flexible bit architecture to configure for resolution and accuracy. Embodiments include a phase shifting electronic circuit employing such VGAs for in-phase and quadrature signal paths, enabling 360° phase coverage, low error beamforming, and adaptability for applications such as radar and satellite communications.

### CROSS-REFERENCE TO RELATED APPLICATION

This application claims the priority benefit under 35 U.S.C. § 119(e) of U.S. Provisional Application No. 63/691,105, filed on Sep. 5, 2024, the disclosure of which is incorporated by reference in its entirety as if fully set forth herein.

### TECHNICAL FIELD

The disclosure generally relates to active radio frequency (RF) phase shifters. More particularly, the subject matter disclosed herein relates to an RF variable gain amplifier (VGA) using a combination of current steering and current cancellation techniques for high resolution RF phase shifters.

### SUMMARY

High resolution RF phase shifters are often used in phase array transceivers to minimize side lobes in a radiated beam. Active RF phase shifters may be preferred over passive architectures for lower area, higher power gain, and higher phase resolution.

FIG. 1 illustrates a diagram of a conventional active phase shifter.

As shown in FIG. 1, active phase shifters 100 split the RF signal 102 into in-phase (I) and quadrature signals (Q) using a passive quadrature coupler 104, apply different amplification to the I and Q signals using RF VGAs 106, 108 according to the phase setting, and combine the amplified I and Q signals as an RF output signal 110.

It can be observed from FIG. 1 that the phase shift is realized by the amplitude (gain) control of I and Q VGAs 106, 108, so phase resolution is determined by the amplitude resolution or the gain steps of the VGAs. Thus, fine and accurate VGA gain steps are necessary to realize high phase resolution.

Two RF VGA architectures, i.e., a current steering VGA 200 and a current cancelling VGA 300, are shown in FIGS. 2A and 3A, respectively. Both of these architectures have a differential common source device pair (e.g., M1P 202, M1N 204 for VGA 200 and M1P 302, M1N 304 for VGA 300) which converts the input differential RF voltage RFᵢₙ into current. Also, both architectures have a current control quad comprising of devices M2P 206, M2N 208, M3P 210, M3N 212 for VGA 200 and M2P 306, M2N 308, M3P 310, M3N 312 for VGA 300. However, as it can be observed in FIGS. 2A and 3A, the connection of the current control quad is different for each architecture. The effective width of devices M2P, M2N, M3P, M3N can be digitally controlled in a binary weighted manner by changing the number of ON/OFF slices. It is to be appreciated that a binary-weighted slice is a section of a circuit whose contribution to the total output is scaled according to a binary weighting—meaning each slice represents a value that is a power of two relative to the others. However, the control scheme must ensure that total width of M2P+M3P and M2N+M3N is always constant.

In the current steering VGA 200 of FIG. 2, M2P 206, M2N 208, M3P 210, M3N 212 have the same maximum width and m-binary weighted slices. The effective width (width of ON slices) of M2P 206 and M3P 210 are changed in opposite directions such that the sum of their effective widths are the same; M2N 208 and M3N 212 are controlled in the same way. FIG. 2A illustrates the gain step of VGA 200 as the width of the binary weighted slices is varied. All binary weighted slices of M2P 206 and M2N 208 are ON (effective device width=W) and all binary weighted slices of M3P 210 and M3N 212 are OFF (effective device width=0) in full-scale mode. Thus, in full-scale mode all the current IRF is driven to the output. In attenuation mode, M2P 206 and M2N 208 are partially ON with effective width of W−wᵤ, so are M3P 210 and M3N 212 with effective width of wᵤ. Thus, only a portion of the current IRF*(W−wᵤ)/W is driven to the output, while the remaining portion IRF*wᵤ/W is dumped to the supply VDD. Thus, attenuation with respect to full scale is 20*log 10((W−wᵤ)/W).

In the current cancelling VGA 300 of FIG. 3, M2P 306, M2N 308, M3P 310, M3N 312 have the same maximum width and n binary weighted slices. (n−1) slices are binary weighted. MSB slice width equals 2ⁿ⁻¹. The effective width (width of ON binary weighted slices) of M2P 306 and M3P 310 are changed in opposite directions such that the sum of their effective widths are the same; M2N 308 and M3N 312 are controlled in the same way. FIG. 3A illustrates the gain step of VGA 300 as the width of the binary weighted slices is varied. All binary weighted slices of M2P 306 and M2N 308 are ON (effective device width=W) and all binary weighted slices of M3P 310 and M3N 312 are OFF (effective device width=0) in full-scale mode. As before, in full-scale mode all the current IRF is driven to the output. In attenuation mode, M2P 306 and M2N 308 are partially ON with effective width of W−wᵤ, so are M3P 310 and M3N 312 with effective width of wᵤ. Here, instead of steering the M3P 310 and M3N 312 current IRF*wᵤ/W to supply VDD, it is subtracted from the current of M2P 306 and M2N 308. Thus, the net output current is (IRF*(W−wᵤ)/W)−(IRF*wᵤ/W)=IRF*((W−2wᵤ)/W), and attenuation with respect to full scale is 20*log 10((W−2wᵤ)/W).

Minimum device width that can be toggled ON/OFF for amplitude control is limited by device technology. With this constraint, the current steering VGA 200 is capable of achieving much finer amplitude control steps compared to the current cancelling VGA 300. On the other hand, the current cancelling VGA 300 has an advantage of realizing larger gain steps for a given change of device width compared to the current steering VGA 200. In other words, the current cancelling VGA 300 can realize the larger gain steps with low output impedance variation, which reduce phase and amplitude error.

Another advantage of the current cancelling VGA 300 is that the current cancelling VGA 300 can achieve a perfect cancellation of the RF signal (i.e., zero output amplitude) when effective widths of M2P 306, M2N 308, M3P 310, M3N 312 are the same. However, current steering VGA 200 can only achieve a certain minimum attenuation value limited by the maximum width of M3P 310 and M3N 312. Increase of M3P 310 and M3N 312 width beyond a certain limit, causes significant input impedance variation degrading phase and amplitude error.

To overcome these issues, given the respective benefits of current steering and current cancelling VGAs, an architecture that combines these two topologies to realize the advantages of both is provided. Using this architecture in the I,Q VGAs of an active phase shifter, resolution and accuracy can be significantly improved.

In an embodiment, a VGA comprising a current cancelling portion and a current steering portion is provided. The current cancelling portion and the current steering portion include a flexible bit architecture for individually configuring a number of bits in each portion. The RF VGA of the present disclosure is a combination of a m-bit current steering VGA and n-bit current cancelling VGA. A number of gain steps or control bits of the current steering VGA portion and the current cancelling VGA portion can be chosen to trade-off between gain resolution and phase variation requirements.

In an embodiment, a phase shifting electronic circuit is provided, which includes an RF signal input that receives an RF signal; a quadrature coupler that splits the received RF signal into in-phase (I) and quadrature (Q) signals; a first VGA configured to receive the in-phase (I) signals including a current cancelling portion and a current steering portion, wherein the current cancelling portion and the current steering portion comprise a flexible bit architecture for individually configuring a number of bits in each portion; a second VGA configured to receive the quadrature (Q) signals including a current cancelling portion and a current steering portion, wherein the current cancelling portion and the current steering portion comprise a flexible bit architecture for individually configuring a number of bits in each portion; and a RF out component connected to the first VGA and the second VGA and configured to combine the in-phase (I) and quadrature (Q) signals amplified by the first VGA and the second VGA.

In an embodiment, a method comprises providing a VGA including a n-bit current cancelling portion and a m-bit current steering portion, wherein the current cancelling portion and the current steering portion comprise a flexible bit architecture for individually configuring a number of bits in each portion; selecting a number of n-bits for desired gain steps of the current cancelling portion; and iteratively increasing a number of m-bits until a predetermined phase resolution is reached with a given error tolerance.

The techniques of the present disclosure may provide for i.) simultaneous high gain step resolution and low phase variation, ii) ability to trade-off gain step resolution and phase variation in the VGA by choosing the number of gain steps (control bits) in the current steering VGA and the current cancelling VGA; iii) phase inversion ability and iv) 360-degree phase coverage.

### BRIEF DESCRIPTION OF THE DRAWINGS

In the following section, the aspects of the subject matter disclosed herein will be described with reference to exemplary embodiments illustrated in the figures, in which:

FIG. 1 illustrates a diagram of a conventional active phase shifter;

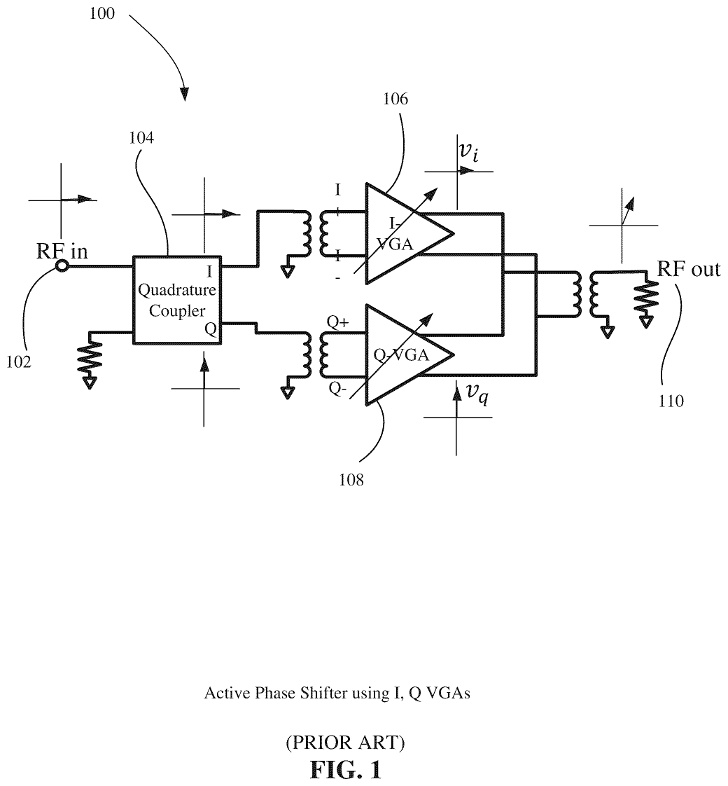

FIG. 2A illustrates a diagram of a conventional current steering variable gain amplifier (VGA);

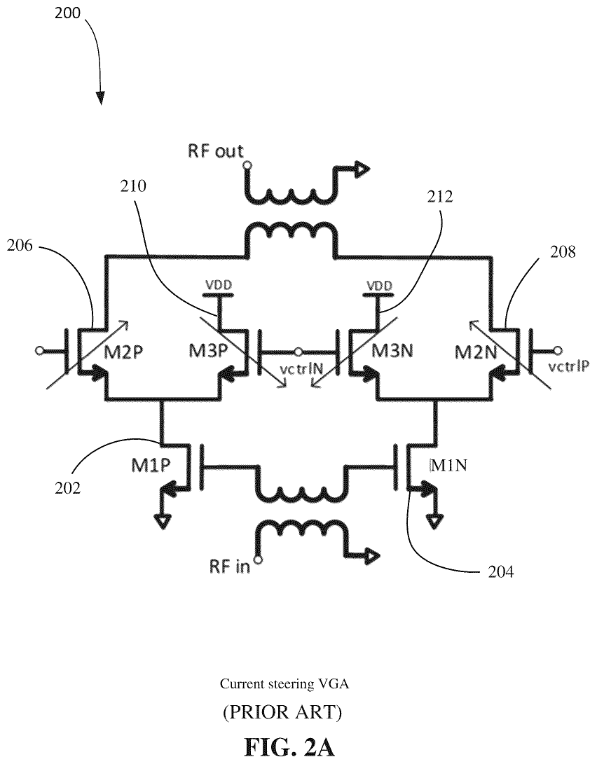

FIG. 2B is a table illustrating gain steps of the current steering variable gain amplifier (VGA) shown in FIG. 2A;

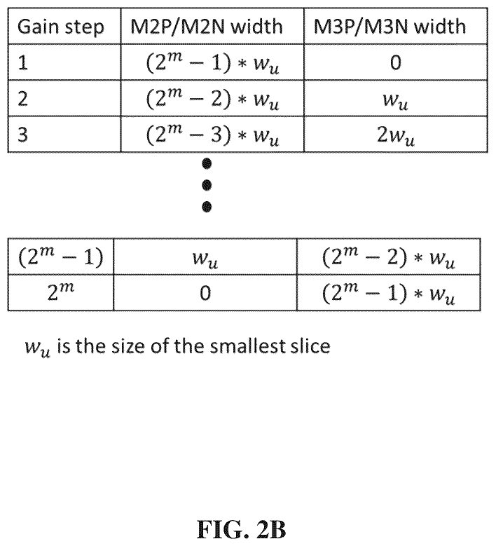

FIG. 3A illustrates a diagram of a conventional current cancelling variable gain amplifier (VGA);

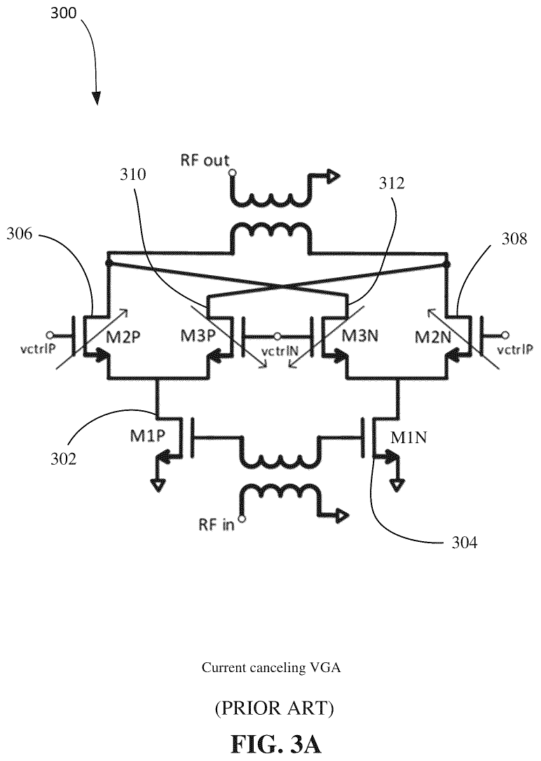

FIG. 3B is a table illustrating gain steps of the current canceling variable gain amplifier (VGA) shown in FIG. 3A;

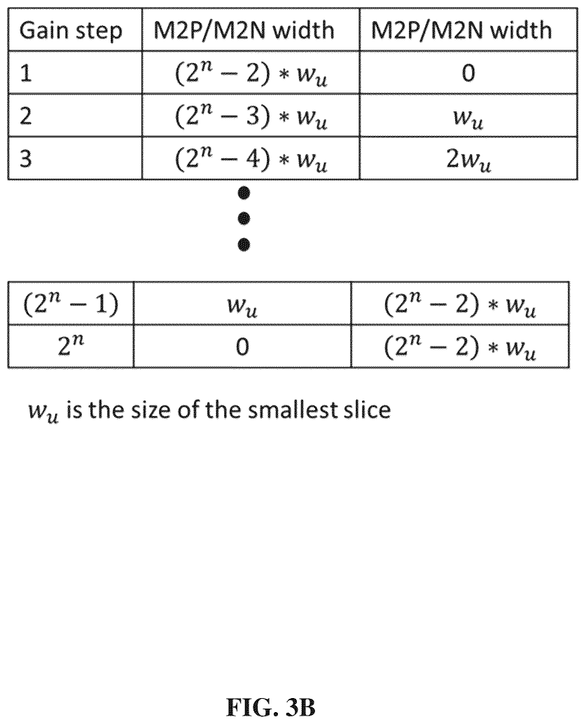

FIG. 4A illustrates a diagram of a current cancelling plus current steering VGA, according to an embodiment;

FIG. 4B is a table illustrating gain steps of the variable gain amplifier (VGA) shown in FIG. 4A, according to an embodiment;

FIG. 5 illustrates a diagram of an active phase shifter using a current cancelling plus current steering VGA, according to an embodiment;

FIG. 6 is a flow chart illustrating a method for configuring a VGA for a desired phase resolution, according to an embodiment;

FIG. 7 is a block diagram of an electronic device in a network environment, according to an embodiment; and

FIG. 8 shows a system including a UE and a gNB in communication with each other.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/of” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

An RF VGA of the present disclosure combines current steering VGA and current cancelling VGA structures to realize the benefits of both architectures. It is to be appreciated that in a current steering VGA, gain control is achieved by steering a portion of the signal away from the output and into AC ground, while in a current cancelling VGA, gain control is achieved by adding a small portion of negative signal to the positive signal at the output. Bigger gain steps may be realized with the current cancelling VGA portion with smaller change in the sizes of the current steering VGA portion. This avoids large changes in output capacitance and gm-device's drain node capacitance ensuring lower phase variation. Smaller gain steps may be realized using the current steering VGA to meet the gain step resolution.

Active RF phase shifters use VGAs to control amplitude of in-phase and quadrature components. To achieve adequate phase resolution and phase error of applications like SATCOM and radar, fine control of VGA gain and low phase variation may be utilized. The fineness of VGA gain control and phase variation may be determined by phase resolution and phase error requirements of the application, e.g., SATCOM (satellite communications), radar, etc.

A current steering VGA may achieve the highest gain step resolution for a given minimum device width. The minimum device width is limited by device technology. However, the output capacitance variation is high because the number of ON devices at the output node changes with gain setting. Variation of capacitance at the drain of the gm-device is also significant due to the same reasons. The capacitance variation may cause a phase error large enough to degrade the phase shifter error requirements. Further, a full attenuation state for 0/90/180/270-degree phase shifts is far from perfect due to current leakage from the OFF devices.

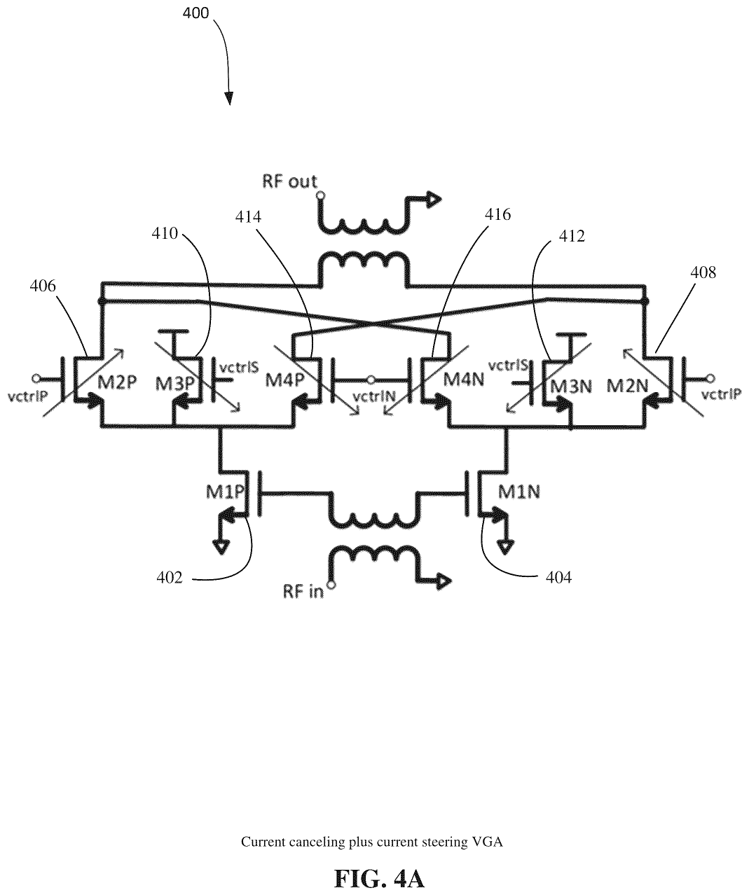

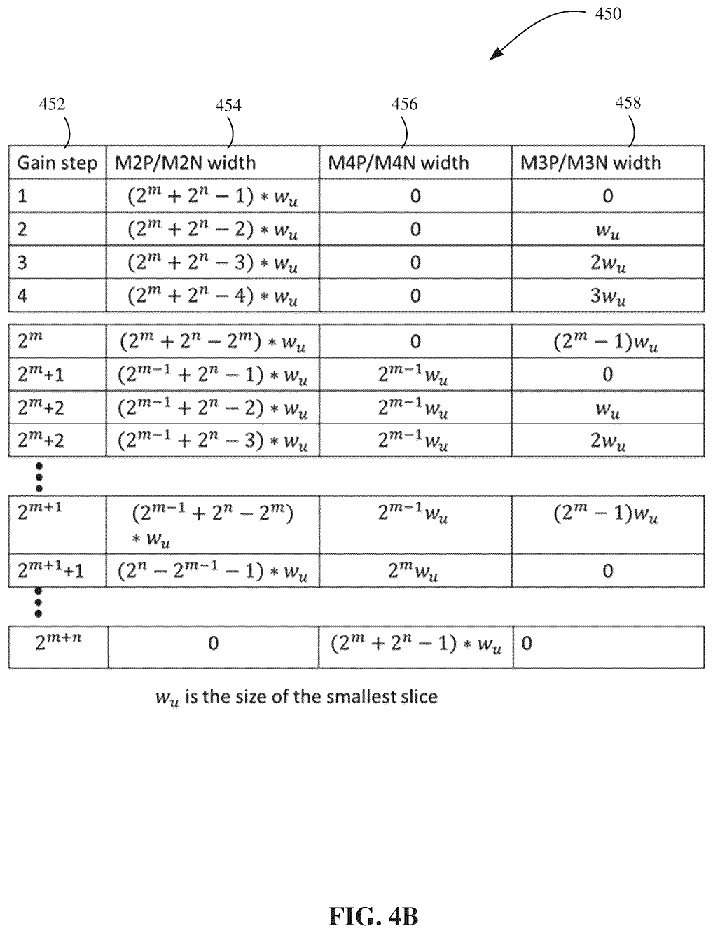

A current cancelling VGA can achieve higher gain steps for a given change in device/slice width, i.e., higher compared to a current steering VGA for the same slice widths while not high enough to meet the phase shifter resolution requirements as dictated by a system specification. The output capacitance variation is lower due to the same number of ON and OFF devices at the output nodes. Variation of capacitance at the drain of the gm-device is also low due to the same reasons. Maximum attenuation of the input signal may be much closer to target due to the perfect symmetry of hardware components of the circuit as shown in FIG. 4A.

However, it has low gain step resolution for a given minimum device width.

In accordance with an embodiment of the present disclosure, to achieve a high gain step resolution, low phase variation and closer to target full attenuation state, a current cancelling plus current steering VGA 400, as illustrated in FIG. 4A, is provided. The structure 400 has a n-bit current cancelling VGA portion and a m-bit current steering VGA portion. The current steering VGA portion has m-bit binary weighted slices on the devices M3P/M3N to achieve the finest gain steps. The current cancelling VGA portion has (n−1)-bit binary weighted slices on devices M2P/M4P/M2N/M4N and the biggest binary weighted slice equal to the sum of the smaller binary weighted slices to provide the coarse gain steps and the full attenuation steps.

The VGA 400 includes an input stage having a pair of transistors M1P 402 and M1N 404 configured to receive a differential RF input signal RFᵢₙ. The source terminals of transistors M1P 402 and MIN 404 are coupled to a common RF input node through an input transformer, while the drain terminals are respectively connected to transistors 406 and 408.

The current canceling VGA portion comprises transistors M2P 410, M4P 414, M2N 412, and M4N 416. Transistors M2P 410 and M4P 414 are disposed on the positive signal path, while transistors M2N 412 and M4N 416 are disposed on the negative signal path. In this embodiment, these devices are implemented as (n−1)-bitbinary weighted slices, wherein the largest binary weighted slice is equal in weight to the sum of all smaller binary weighted slices. This configuration enables coarse gain adjustment steps as well as the capability to achieve a full attenuation state by appropriately canceling current through complementary conduction paths.

The current steering VGA portion includes transistors M3P 410 and M3N 412 coupled respectively to nodes 406 and 408. The transistors M3P 410 and M3N 412 are implemented in m-bit binary weighted slices, enabling fine gain resolution. The m-bit configuration allows for precise steering of current between the load paths to achieve the smallest incremental gain steps. The fine resolution of the current steering portion is matched to the coarse resolution of the current canceling portion to ensure uniform gain transitions.

In operation, control signals vctrlP, vctrlS, and vctrlIN are applied to the respective gate terminals of the transistors in the current canceling and current steering portions. The current steering VGA portion (M3P/M3N) is configured such that its most significant bit (MSB) slice is equal in size to the least significant bit (LSB) slice of the current canceling VGA portion (M2P/M4P/M2N/M4N). This matching of bit-slice sizes enables seamless transitions between the fine and coarse gain adjustments, producing uniform gain steps with minimal phase discontinuity. The drains of transistors M4P 414 and M4N 416 are coupled to a transformer-based load network, which delivers the processed signal to an RF output port.

The table 450 in FIG. 4B illustrates a control scheme of the binary weighted slices to achieve uniform steps and uniform output capacitance. In FIG. 4B, column 452 represents gain steps of the VGA, column 454 represents the effective transistor width allocated to the M2P/M2N pair of devices, column 456 represents the effective transistor width allocated to the M4P/M4N pair of devices, and column 458 represents the effective transistor width allocated to the M3P/M3N pair of devices. Each row corresponds to gain steps, showing how widths are reassigned to the transistor pairs in binary increments. Here, the sum of the device widths is same for all gain steps. The effective width (width of ON slices) of M2P and M3P/M4P may be changed in opposite directions such that the sum of their effective widths (M2P+M3P+M4P) may be the same. M2N, M3N, M4N may be controlled in the same way.

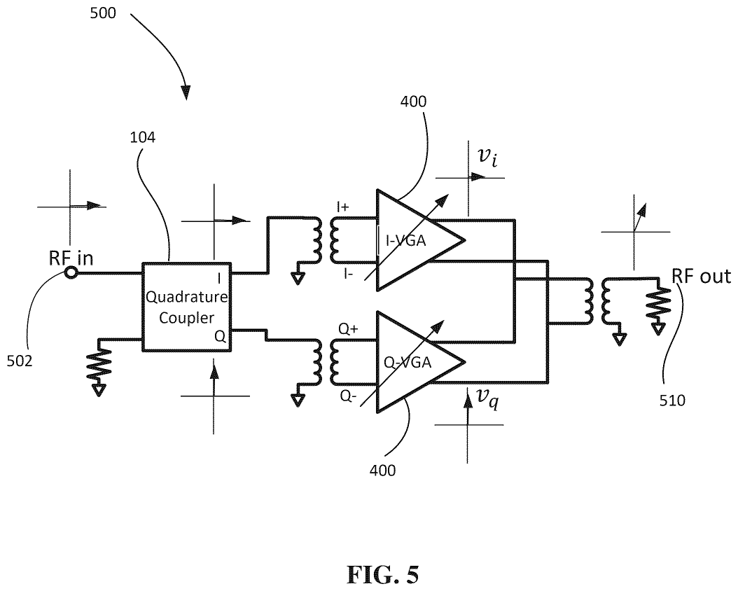

FIG. 5 illustrates a phase shifter 500 that uses a current cancelling plus current steering VGA 400 to achieve phase resolution and phase error system requirements. To minimize the phase error of the phase shifter 500, a number of bits in the current cancelling VGA portion can be chosen such that the bigger gain steps may be approximate to the target or calculated values of the phase shifter system requirements. Once the number of bits in the current cancelling VGA portion is determined, the number of bits of the current steering bits can be increased from 0 to m till the target or calculated phase error requirement is satisfied.

Referring now to FIG. 5, the system 500 is configured to receive an RF input signal at an RF input port 502 and to provide an amplified RF output signal at an RF output port 510.

The RF input signal is provided to a quadrature coupler 104, which is configured to split the RF input signal into an in-phase (I) component and a quadrature (Q) component. The quadrature coupler 104 outputs a pair of differential signals I+ and I− corresponding to the in-phase component, and a pair of differential signals Q+ and Q− corresponding to the quadrature component.

The differential in-phase signals I+ and I− are coupled to a first variable gain amplifier (VGA) 400, which may be implemented using the current canceling plus current steering VGA architecture described with respect to FIG. 4A. The first VGA 400 produces an amplified in-phase output signal vᵢ. Similarly, the differential quadrature signals Q+ and Q− are coupled to a second VGA 400, also implemented as described with respect to FIG. 4A, to produce an amplified quadrature output signal v_{q}.

The amplified in-phase and quadrature signals vᵢ and v_{q} are then combined through a signal combining network to form the final RF output signal provided at the RF output port 510.

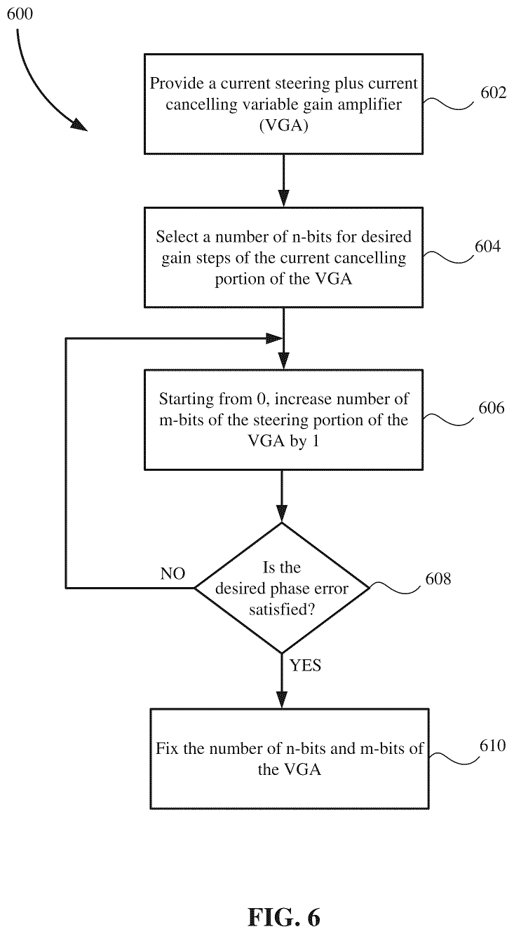

Referring to FIG. 6, a flow chart illustrating a method 600 for configuring a VGA for a desired phase resolution is provided. Initially, in step 602, a current steering plus current cancelling VGA is provided. The current cancelling portion and the current steering portion of the VGA comprise a flexible bit architecture such that the number of bits in each portion is individually configurable. In step 604, a number of n-bits is selected for desired gain steps of the current cancelling portion. In step 606, starting from 0, a number of m-bits is increased until a predetermined phase resolution with a given error tolerance is reached. In step 608, it is determined if the phase resolution is within the error tolerance, and if not, the method reverts to step 606 to increase the number of m-bits by 1. If in step 608, the phase resolution is within the error tolerance, then the number of n-bits and m-bits is fixed, in step 610.

It is to be appreciated that the method 600 may be performed for each path in circuit 500, i.e., in-phase (I) and a quadrature (Q) path. A given phase step (Phi) determines a gain step Gi for I VGA and a gain step Gq for Q VGA. These are different and have different errors. So the method 600 is performed separately for each VGA to minimize error in Gi and Gq and would give the settings for minimum error in Phi.

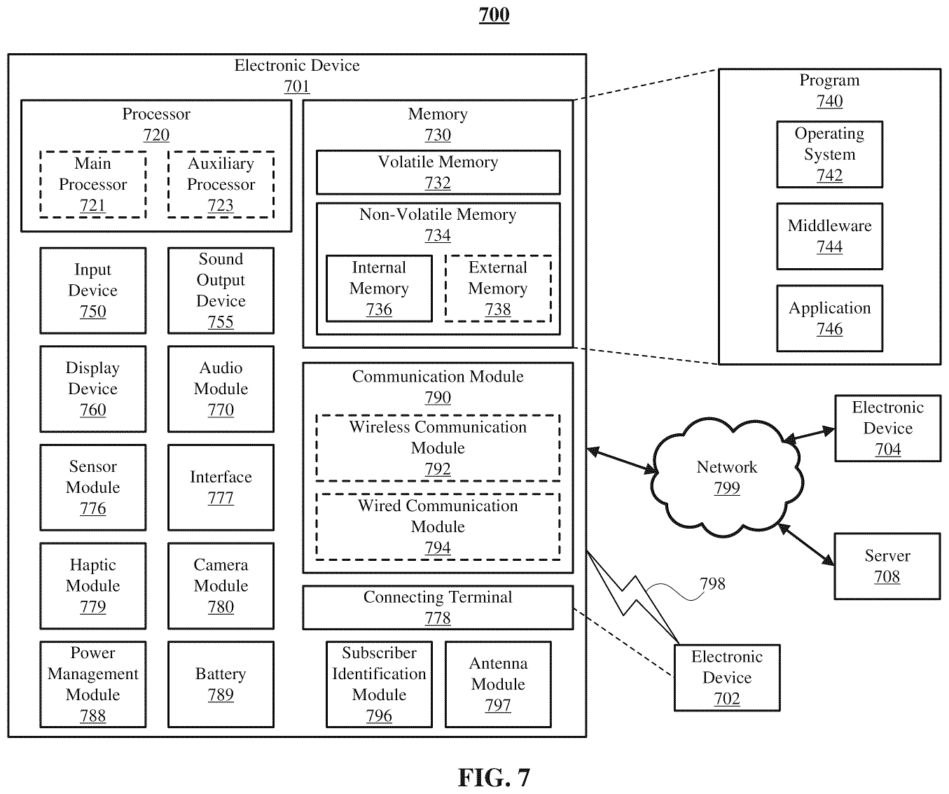

FIG. 7 is a block diagram of an electronic device in a network environment 700, according to an embodiment.

Referring to FIG. 7, an electronic device 701 in a network environment 700 may communicate with an electronic device 702 via a first network 798 (e.g., a short-range wireless communication network), or an electronic device 704 or a server 708 via a second network 799 (e.g., a long-range wireless communication network). The electronic device 701 may communicate with the electronic device 704 via the server 708. The electronic device 701 may include a processor 720, a memory 730, an input device 750, a sound output device 755, a display device 760, an audio module 770, a sensor module 776, an interface 777, a haptic module 779, a camera module 780, a power management module 788, a battery 789, a communication module 790, a subscriber identification module (SIM) card 796, or an antenna module 797. In one embodiment, at least one (e.g., the display device 760 or the camera module 780) of the components may be omitted from the electronic device 701, or one or more other components may be added to the electronic device 701. Some of the components may be implemented as a single integrated circuit (IC). For example, the sensor module 776 (e.g., a fingerprint sensor, an iris sensor, or an illuminance sensor) may be embedded in the display device 760 (e.g., a display).

The processor 720 may execute software (e.g., a program 740) to control at least one other component (e.g., a hardware or a software component) of the electronic device 701 coupled with the processor 720 and may perform various data processing or computations.

As at least part of the data processing or computations, the processor 720 may load a command or data received from another component (e.g., the sensor module 776 or the communication module 790) in volatile memory 732, process the command or the data stored in the volatile memory 732, and store resulting data in non-volatile memory 734. The processor 720 may include a main processor 721 (e.g., a central processing unit (CPU) or an application processor (AP)), and an auxiliary processor 723 (e.g., a graphics processing unit (GPU), an image signal processor (ISP), a sensor hub processor, or a communication processor (CP)) that is operable independently from, or in conjunction with, the main processor 721. Additionally or alternatively, the auxiliary processor 723 may be adapted to consume less power than the main processor 721, or execute a particular function. The auxiliary processor 723 may be implemented as being separate from, or a part of, the main processor 721.

The auxiliary processor 723 may control at least some of the functions or states related to at least one component (e.g., the display device 760, the sensor module 776, or the communication module 790) among the components of the electronic device 701, instead of the main processor 721 while the main processor 721 is in an inactive (e.g., sleep) state, or together with the main processor 721 while the main processor 721 is in an active state (e.g., executing an application). The auxiliary processor 723 (e.g., an image signal processor or a communication processor) may be implemented as part of another component (e.g., the camera module 780 or the communication module 790) functionally related to the auxiliary processor 723.

The memory 730 may store various data used by at least one component (e.g., the processor 720 or the sensor module 776) of the electronic device 701. The various data may include, for example, software (e.g., the program 740) and input data or output data for a command related thereto. The memory 730 may include the volatile memory 732 or the non-volatile memory 734. Non-volatile memory 734 may include internal memory 736 and/or external memory 738.

The program 740 may be stored in the memory 730 as software, and may include, for example, an operating system (OS) 742, middleware 744, or an application 746.

The input device 750 may receive a command or data to be used by another component (e.g., the processor 720) of the electronic device 701, from the outside (e.g., a user) of the electronic device 701. The input device 750 may include, for example, a microphone, a mouse, or a keyboard.

The sound output device 755 may output sound signals to the outside of the electronic device 701. The sound output device 755 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 760 may visually provide information to the outside (e.g., a user) of the electronic device 701. The display device 760 may include, for example, a display, a hologram device, or a projector and control circuitry to control a corresponding one of the display, hologram device, and projector. The display device 760 may include touch circuitry adapted to detect a touch, or sensor circuitry (e.g., a pressure sensor) adapted to measure the intensity of force incurred by the touch.

The audio module 770 may convert a sound into an electrical signal and vice versa. The audio module 770 may obtain the sound via the input device 750 or output the sound via the sound output device 755 or a headphone of an external electronic device 702 directly (e.g., wired) or wirelessly coupled with the electronic device 701.

The sensor module 776 may detect an operational state (e.g., power or temperature) of the electronic device 701 or an environmental state (e.g., a state of a user) external to the electronic device 701, and then generate an electrical signal or data value corresponding to the detected state. The sensor module 776 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 777 may support one or more specified protocols to be used for the electronic device 701 to be coupled with the external electronic device 702 directly (e.g., wired) or wirelessly. The interface 777 may include, for example, a high-definition multimedia interface (HDMI), a universal serial bus (USB) interface, a secure digital (SD) card interface, or an audio interface.

A connecting terminal 778 may include a connector via which the electronic device 701 may be physically connected with the external electronic device 702. The connecting terminal 778 may include, for example, an HDMI connector, a USB connector, an SD card connector, or an audio connector (e.g., a headphone connector).

The haptic module 779 may convert an electrical signal into a mechanical stimulus (e.g., a vibration or a movement) or an electrical stimulus which may be recognized by a user via tactile sensation or kinesthetic sensation. The haptic module 779 may include, for example, a motor, a piezoelectric element, or an electrical stimulator.

The camera module 780 may capture a still image or moving images. The camera module 780 may include one or more lenses, image sensors, image signal processors, or flashes. The power management module 788 may manage power supplied to the electronic device 701. The power management module 788 may be implemented as at least part of, for example, a power management integrated circuit (PMIC).

The battery 789 may supply power to at least one component of the electronic device 701. The battery 789 may include, for example, a primary cell which is not rechargeable, a secondary cell which is rechargeable, or a fuel cell.

The communication module 790 may support establishing a direct (e.g., wired) communication channel or a wireless communication channel between the electronic device 701 and the external electronic device (e.g., the electronic device 702, the electronic device 704, or the server 708) and performing communication via the established communication channel. The communication module 790 may include one or more communication processors that are operable independently from the processor 720 (e.g., the AP) and supports a direct (e.g., wired) communication or a wireless communication. The communication module 790 may include a wireless communication module 792 (e.g., a cellular communication module, a short-range wireless communication module, or a global navigation satellite system (GNSS) communication module) or a wired communication module 794 (e.g., a local area network (LAN) communication module or a power line communication (PLC) module). A corresponding one of these communication modules may communicate with the external electronic device via the first network 798 (e.g., a short-range communication network, such as BLUETOOTH™, wireless-fidelity (Wi-Fi) direct, or a standard of the Infrared Data Association (IrDA)) or the second network 799 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 792 may identify and authenticate the electronic device 701 in a communication network, such as the first network 798 or the second network 799, using subscriber information (e.g., international mobile subscriber identity (IMSI)) stored in the subscriber identification module 796.

The antenna module 797 may transmit or receive a signal or power to or from the outside (e.g., the external electronic device) of the electronic device 701. The antenna module 797 may include one or more antennas, and, therefrom, at least one antenna appropriate for a communication scheme used in the communication network, such as the first network 798 or the second network 799, may be selected, for example, by the communication module 790 (e.g., the wireless communication module 792). The signal or the power may then be transmitted or received between the communication module 790 and the external electronic device via the selected at least one antenna.

Commands or data may be transmitted or received between the electronic device 701 and the external electronic device 704 via the server 708 coupled with the second network 799. Each of the electronic devices 702 and 704 may be a device of a same type as, or a different type, from the electronic device 701. All or some of operations to be executed at the electronic device 701 may be executed at one or more of the external electronic devices 702, 704, or 708. For example, if the electronic device 701 should perform a function or a service automatically, or in response to a request from a user or another device, the electronic device 701, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 701. The electronic device 701 may provide the outcome, with or without further processing of the outcome, as at least part of a reply to the request. To that end, a cloud computing, distributed computing, or client-server computing technology may be used, for example.

In the context of electronic device 701 shown in the FIG. 7, a phase shifter 500 would be embodied within or in association with the antenna module 797. The phase shifter 500 may be operatively controlled by the processor 720 (e.g., main processor 721 or auxiliary processor 723), such that the device can dynamically adjust the phase of transmit and/or receive signals across one or more antenna elements. By altering the relative phase of signals, the antenna module can perform beamforming or beamsteering operations, thereby improving link quality, reducing interference, and enhancing throughput when communicating with external devices (e.g., electronic device 704, server 708, etc.) over the network 799. In some embodiments, the memory 730 may store program instructions that configure phase shift control algorithms as shown and described in relation to FIG. 6, while the processor 720 executes those instructions to set phase shift values of the VGAs in real time.

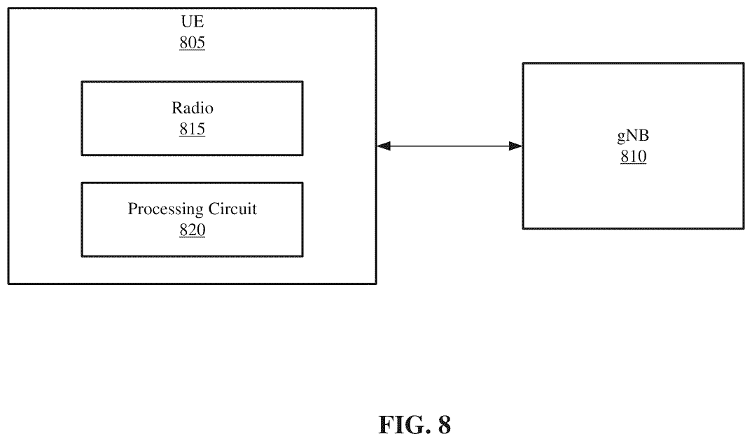

FIG. 8 shows a system including a UE 805 and a gNB 810, in communication with each other. The UE may include a radio 815 and a processing circuit (or a means for processing) 820, which may perform various methods disclosed herein, e.g., the method illustrated in FIG. 6. For example, the processing circuit 820 may receive, via the radio 815, transmissions from the network node (gNB) 810, and the processing circuit 820 may transmit, via the radio 815, signals to the gNB 810.

In one embodiment, the UE 805 may further include phase shifter 500 operatively coupled to the radio 815 and one or more antennas of the UE 805. The phase shifter 500 may be configured to adjust a phase of signals transmitted and/or received via the antennas. The processing circuit 820 may perform the method 600 and calculate or determine the gain steps and phase error requirements of the phase shifter 500, and may control the VGAs of phase shifter 825 accordingly. By dynamically adjusting the phase of antenna signals, the UE 805 may perform analog beamforming, hybrid beamforming, or other beam management techniques, thereby improving link quality with the gNB 810, reducing interference, and enhancing throughput and reliability of wireless communication.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus.

Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A variable gain amplifier (VGA) comprising:
a current cancelling portion;
a current steering portion; and
wherein the current cancelling portion and the current steering portion comprise a flexible bit architecture for individually configuring a number of bits in each portion.

2. The VGA of claim 1, wherein the current cancelling portion includes a first gain step size and the current steering portion includes a second gain step size, the first gain step size being greater than the second gain step size.

3. The VGA of claim 2, wherein a number of first gain steps and a number of second gain steps are configurable to a desired resolution of the VGA.

4. The VGA of claim 1, wherein the current cancelling portion includes a first predetermined bit number (n−1) of binary weighted slices, a largest binary weighted slice being equal to a sum of smaller binary weighted slices to provide course gain steps.

5. The VGA of claim 4, wherein the current steering portion includes a second predetermined bit number (m) of binary weighted slices to provide fine gain steps.

6. The VGA of claim 5, wherein a least significant bit (LSB) slice of the current cancelling portion is equal to a most significant bit (MSB) of the current steering portion to provide uniform gain steps.

7. The VGA of claim 6, wherein a sum of the binary weighted slices is the same for all gain steps.

8. A phase shifting electronic circuit, comprising:
a radio frequency (RF) signal input that receives an RF signal;
a quadrature coupler that splits the received RF signal into in-phase (I) and quadrature (Q) signals;
a first variable gain amplifier (VGA) configured to receive the in-phase (I) signals, the first VGA including a current cancelling portion and a current steering portion, wherein the current cancelling portion and the current steering portion include a flexible bit architecture for individually configuring a number of bits in each portion;
a second VGA configured to receive the quadrature (Q) signals, the second VGA including a current cancelling portion and a current steering portion, wherein the current cancelling portion and the current steering portion include a flexible bit architecture for individually configuring a number of bits in each portion; and
an RF out component connected to the first VGA and the second VGA and configured to combine the in-phase (I) and quadrature (Q) signals amplified by the first VGA and the second VGA.

9. The phase shifting electronic circuit of claim 8, wherein the current cancelling portion of the first and second VGA includes a first gain step size and the current steering portion of the first and second VGA includes a second gain step size, the first gain step size being greater than the second gain step size.

10. The phase shifting electronic circuit of claim 9, wherein a number of first gain steps and a number of second gain steps are configurable to a desired resolution of the first and second VGA.

11. The phase shifting electronic circuit of claim 8, wherein the current cancelling portion of the first and second VGA includes a first predetermined bit number (n−1) of binary weighted slices, a largest binary weighted slice being equal to a sum of smaller binary weighted slices to provide course gain steps.

12. The phase shifting electronic circuit of claim 11, wherein the current steering portion of the first and second VGA includes a second predetermined bit number (m) of binary weighted slices to provide fine gain steps.

13. The phase shifting electronic circuit of claim 12, wherein a least significant bit (LSB) slice of the current cancelling portion is equal to a most significant bit (MSB) of the current steering portion to provide uniform gain steps.

14. The phase shifting electronic circuit of claim 13, wherein a sum of the binary weighted slices is the same for all gain steps.

15. A method comprising:
providing a variable gain amplifier (VGA) including a n-bit current cancelling portion and a m-bit current steering portion, wherein the current cancelling portion and the current steering portion comprise a flexible bit architecture for individually configuring a number of bits in each portion;
selecting a number of n-bits for desired gain steps of the current cancelling portion; and
iteratively increasing a number of m-bits until a predetermined phase error is reached.

16. The method of claim 15, wherein the current cancelling portion includes a first gain step size and the current steering portion includes a second gain step size, the first gain step size being greater than the second gain step size.

17. The method of claim 15, wherein the current cancelling portion includes a first predetermined bit number (n−1) of binary weighted slices, a largest binary weighted slice being equal to a sum of smaller binary weighted slices to provide course gain steps.

18. The method of claim 17, wherein the current steering portion includes a second predetermined bit number (m) of binary weighted slices to provide fine gain steps.

19. The method of claim 18, wherein a least significant bit (LSB) slice of the current cancelling portion is equal to a most significant bit (MSB) of the current steering portion to provide uniform gain steps.

20. The method of claim 19, wherein a sum of the binary weighted slices is the same for all gain steps.
